(19) United States
(12) Patent Application Publication
(10) Pub. No.: US 2006/0001554 A1
(43) Pub. Date: Jan. 5, 2006

(54) Video signal reception apparatus and video signal reception method

(75) Inventor: Tatsuo Morishita, Kumagaya-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/169,297

(22) Filed: Jun. 29, 2005

(30) Foreign Application Priority Data
Jun. 30, 2004 (JP) 2004-193769

(51) Int. Cl. H03M 7/00

(52) U.S. Cl. 341/50

(57) ABSTRACT

A control unit selects an analog audio signal output from an audio information processing unit, if a digital audio signal received via an HDMI connector is present. If not, the control unit selects an analog audio signal output from an analog audio signal input unit.

### CROSS-REFERENCE TO RELATED APPLICATIONS

This application is based upon and claims the benefit of priority from prior Japanese Patent Application No. 2004-193769, filed Jun. 30, 2004, the entire contents of which are incorporated herein by reference.

### BACKGROUND OF THE INVENTION

1. Field of the Invention

The present invention relates to a standardized digital transmission system for transmitting a digital video signal obtained by multiplexing digital audio signals and, more particularly, to a video signal reception apparatus and video signal reception method for receiving the digital video signal, and performing specific control for an audio signal system.

2. Description of the Related Art

As disclosed in Jpn. Pat. Appln. KOKAI Publication No. 9-128182, in recent years, a digital video device which receives and outputs a digital video signal has greatly prevailed. As is known well, a DVI (Digital Visual Interface) standard is widely used as a standard for transmitting the digital video signal. Also, recently, an HDMI (High Definition Multimedia Interface) standard is used as a digital signal transmission standard by further improving this DVI standard.

This HDMI standard includes various elements capable of, e.g., transmitting audio data by multiplexing digital audio signals during the blanking period of the digital video signal, transmitting the digital video signal in a color difference YCbCr format in addition to an RGB format, and connecting units via a USB (Universal Serial Bus)-like small HDMI connector. These elements are not included in the DVI standard.

Since the HDMI standard is versatile as described above, a device, display apparatus, and the like each having the HDMI connector will be widely used. However, when the digital transmission system complying with this HDMI standard is to be built, various elements which are not included in the transmission system complying with the DVI standard must be considered.

For example, while the digital audio signal can be transmitted according to the HDMI standard, an analog audio signal is transmitted in a system different from that of the digital audio signal according to the transmission system complying with the DVI standard. This leads to an increase in a product price and complicates a structure around a cable connection, when independently arranging the connectors complying with the HDMI standard and DVI standard.

### BRIEF SUMMARY OF THE INVENTION

In the present invention, the video signal reception apparatus selects the analog audio signal from the audio information processing unit when the digital audio signal received via the HDMI connector is present, and selects the analog audio signal from the analog audio signal input unit when the digital audio signal is absent.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram showing the example of the schematic arrangement of a video signal reception apparatus;

FIG. 2 is a block diagram showing the example of the schematic arrangement of an HDMI signal processing unit in the video signal reception apparatus shown in FIG. 1;

FIG. 3 is a flowchart for explaining the example of the operation of the video signal reception apparatus shown in FIG. 1; and

FIG. 4 is a flowchart for explaining the example of the operation of the HDMI signal processing unit in the video signal reception apparatus shown in FIG. 1.

### DETAILED DESCRIPTION OF THE INVENTION

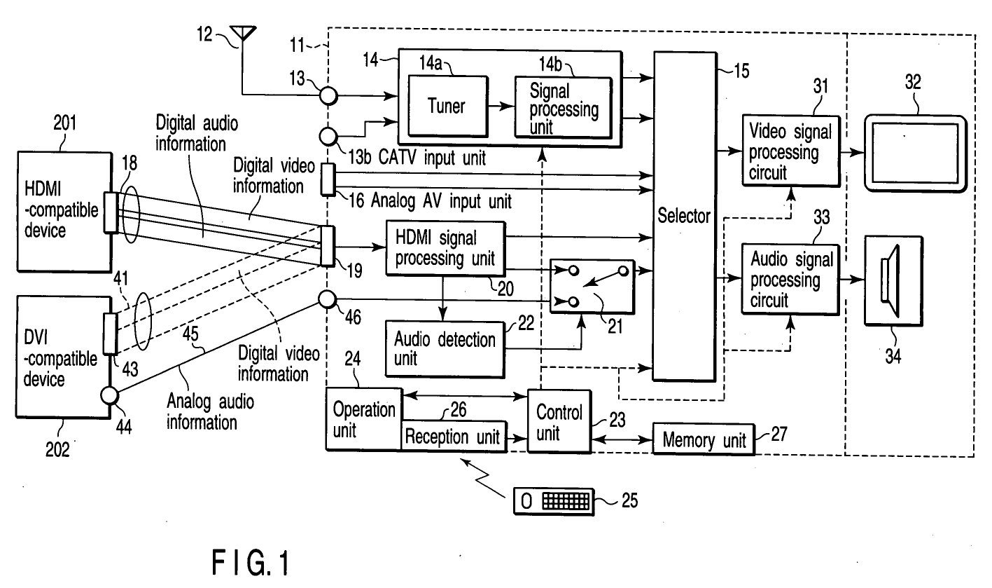

An embodiment of the present invention will be described in detail below with reference to the accompanying drawing. FIG. 1 is a block diagram showing the example of the schematic arrangement of a video signal reception apparatus 11 in the present invention. This video signal reception apparatus 11 includes functions of receiving a TV (television) broadcast signal, an analog video signal and analog audio signal, and a digital video signal complying with an HDMI standard.

That is, the TV broadcast signal is received by an antenna 12, and then supplied to a TV signal processing unit 14 via a TV input terminal 13. This TV signal processing unit 14 extracts a predetermined channel signal from the input TV broadcast signal by using a tuner unit 14a, reconstructs the analog video signal and analog audio signal by using a signal processing unit 14b, and then outputs the reconstructed signals to a selector 15. The TV signal processing unit 14 can also receive a signal from, e.g., a CATV (Cable television) input terminal 13b.

The analog video signal and analog audio signal are received by an AV (Audio Video) input terminal 16, and directly output to the selector 15.

The digital video signal and digital audio signal supplied from an external device 201 via an HDMI cable bus 18 complying with the HDMI standard are received by an HDMI connector 19. As the external device 201, an STB (Set-Top Box), DVD (Digital Video Disc) device, or the like having the HDMI connector complying with the HDMI standard is available. However, some devices realized before the HDMI standard has prevailed do not have the HDMI connectors.

A DVI-compatible device 202 can be connected to the HDMI connector 19 via a conversion cable bus 41. The DVI-compatible device 202 is, e.g., a personal computer which includes a terminal 43 for outputting the digital video signal, and a terminal 44 for outputting the analog audio signal. Therefore, when the DVI-compatible device 202 is connected to the HDMI connector 19, the conversion cable bus 41 is used, and the terminal 44 for outputting the analog audio signal is independently connected to an analog audio signal input terminal 46 via an analog audio cable 45.

A signal output from the HDMI connector 19 is supplied to an HDMI signal processing unit 20. This HDMI signal processing unit 20 (to be described later in detail) reconstructs the analog video signal and analog audio signal from the digital signal complying with the input HDMI standard, and outputs the reconstructed analog signals to the selector 15.

Note that the analog audio signal is input to the selector 15 via a switch 21. The switch 21 selects one of the analog audio signals from the HDMI signal processing unit 20 and the analog audio signal input terminal 46. The selected analog audio signal is output to the selector 15.

On the basis of the control signal from an audio detection unit 22, the switch 21 is controlled. That is, the audio detection unit 22 determines whether the HDMI signal processing unit 20 processes the digital audio signal, and then the switch 21 is controlled on the basis of the determination result (control signal). If the digital audio signal is processed, the switch 21 selects the analog audio signal output from the HDMI signal processing unit 20. If not, the switch 21 selects the analog audio signal from the analog audio signal input terminal 46.

The selector 15 selectively switches between the analog video signal and analog audio signal output from the TV signal processing unit 14, the analog video signal and analog audio signal supplied to the AV input terminal 16, and the analog video signal and analog audio signal respectively output from the HDMI signal processing unit 20 and the switch 21. The analog video signal is supplied to a video signal processing circuit 31, and the analog audio signal is supplied to an audio signal processing circuit 33. The output from the video signal processing circuit 31 is supplied to a display unit 32, and the output from the audio signal processing circuit 33 is supplied to a loudspeaker system 34.

In this video signal reception apparatus 11, a control unit 23 totally controls all operations such as receiving of the above-described various signals. This control unit 23 includes a CPU (Central Processing Unit) and the like to receive operation information from an operation unit 24, or operation information from a remote controller 25 via a reception unit 26. The control unit 23 also controls the units to reflect the operation contents to these units.

In this case, the control unit 23 uses a memory unit 27. That is, this memory unit 27 mainly includes a read-only memory which stores a control program to be executed by the CPU in the control unit 23, a read/write memory which supplies a work area to this CPU, and a nonvolatile memory which stores various pieces of setting information and control information.

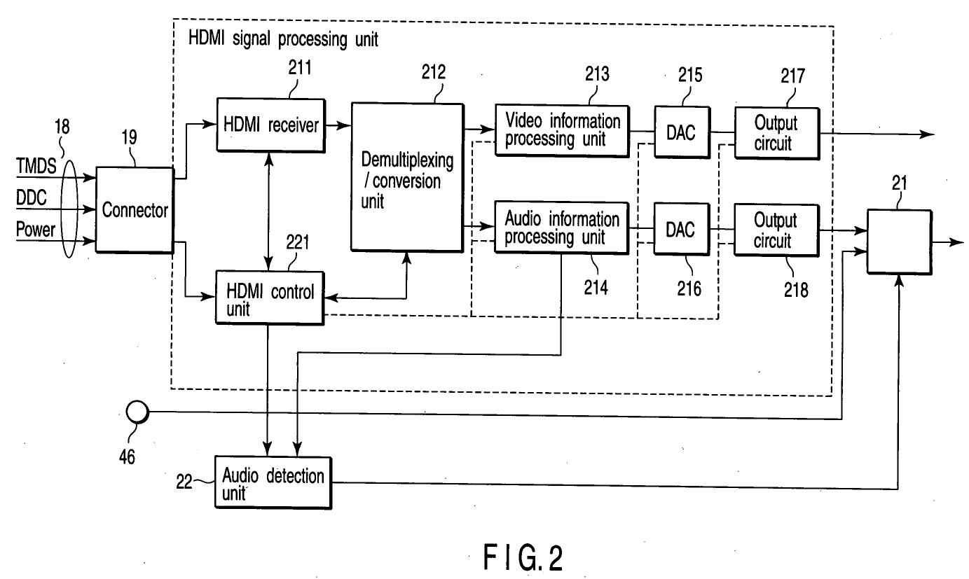

FIG. 2 is a block diagram showing the example of the schematic arrangement of the HDMI signal processing unit 20. The HDMI cable bus 18 serving as a digital transmission bus complying with the HDMI standard mainly includes three types of lines called TMDS, DDC, and Power.

Of these lines, the line TMDS is used to transmit the digital video signal and digital audio signal complying with the HDMI standard, from the HDMI-compatible device 201 to the HDMI connector 19 in the video signal reception apparatus 11. This line TMDS can also transmit the digital video signal from the DVI-compatible device 202.

The line DDC is used to transmit control data, a synchronous clock, and the like between the HDMI-compatible device 201 and the video signal reception apparatus 11.

The line Power is used to apply a constant voltage of, e.g., about 5 V from the HDMI-compatible device 201 to the HDMI connector 19. In this case, the video signal reception apparatus 11 determines whether the HDMI-compatible device 201 is connected to the HDMI connector 19 by checking the voltage level of the line Power connecting to the HDMI connector 19. That is, a constant voltage of, e.g., about 5 V from the HDMI-compatible device 201 serves as a connection recognition signal.

The digital signal complying with the HDMI standard, which is received via the HDMI connector 19 is supplied to an HDMI receiver 211. This HDMI receiver 211 receives a signal in synchronism with the input digital signal, and outputs the received signal to a subsequent demultiplexing/conversion unit 212. The demultiplexing/conversion unit 212 demultiplexes a video component from an audio component, and converts these components into respective signals respectively applying to the display system and the loudspeaker system.

The digital video signal output from the demultiplexing/conversion unit 212 is output to a video information processing unit 213, and the digital audio signal from the demultiplexing/conversion unit 212 is output to an audio information processing unit 214. In the video information processing unit 213, MPEG (Moving Picture Experts Group) decoding processing is executed for the input video component, and the decoded output is output to a digital/analog conversion unit 215. The digital/analog conversion unit 215 converts the output from the video information processing unit 213 into the analog video signal, and outputs the analog video signal via an output circuit 217.

In the audio information processing unit 214, for example, linear PCM (Pulse Code Modulation) decoding processing is executed for the input audio component, and the decoded output is output to a digital/analog conversion unit 216. Alternatively, in the audio information processing unit 214, Dolby-compatible processing, AC3-compatible processing, or MPEG-compatible processing is executed for the input audio component, and the decoded output is output to the digital/analog conversion unit 216. The digital/analog conversion unit 216 converts the output from the audio information processing unit 214 into an analog audio signal, and outputs the analog audio signal via an output circuit 218.

The HDMI signal processing unit 20 incorporates an HDMI control unit 221. For example, the HDMI control unit 221 incorporates a microcomputer to reflect an instruction from the control unit 23 to the functions of the HDMI signal processing unit 20. Additionally, the HDMI signal processing unit 20 can analyze the control data transmitted via the line DDC, and reflect the analysis result to the functions of the HDMI signal processing unit 20.

When detecting the occurrence of change in the predetermined data in the received digital signal, the HDMI receiver 211 outputs the detection signal to an audio mute control unit (not shown). The HDMI control unit 221 monitors the voltage level of the line Power connecting to the HDMI connector 19. When detecting the occurrence of change in the voltage level, the HDMI control unit 221 detects the insertion and extraction of the HDMI connector 19, and outputs the detection signal to an audio mute control unit (not shown). The audio mute control unit outputs a mute signal to the digital/analog conversion unit 216 and the output circuit 218 on the basis of the detection signal from the HDMI receiver 211 or the HDMI control unit 221.

The audio detection unit 22 may be included in the HDMI control unit 221. This audio detection unit 22 detects whether the digital audio information is present in the audio information processing unit 214. Alternatively, the audio detection unit 22 detects whether the digital audio information is present in the output level of the output circuit 218. The presence of the digital audio information means that the digital audio signal is transmitted via the HDMI connector 19. At this time, the audio detection unit 22 controls the switch 21 to select the output from the output circuit 218. If the digital audio information is absent, the DVI-compatible device 202 may be connected to the HDMI connector 19 via the conversion cable bus 41 at a high possibility. Hence, the audio detection unit 22 controls the switch 21 to select the output from the analog audio signal input terminal 46. With this processing, both the signal from the device having the HDMI connector complying with the HDMI standard, and the signal from the device having the connector complying with the DVI standard can be easily received.

As the method of detecting whether the digital audio signal is present, various methods are available. For example, the HDMI control unit 221 may determine the presence of the digital audio signal by, e.g., attribute information pertaining to the acquired audio signal. As the attribute information pertaining to audio data, the sampling frequency, channel count, and the like of the audio data are used. In addition to these, as the attribute information pertaining to the audio data, identification information representing the type of a compression scheme, and identification information representing a PCM scheme are available.

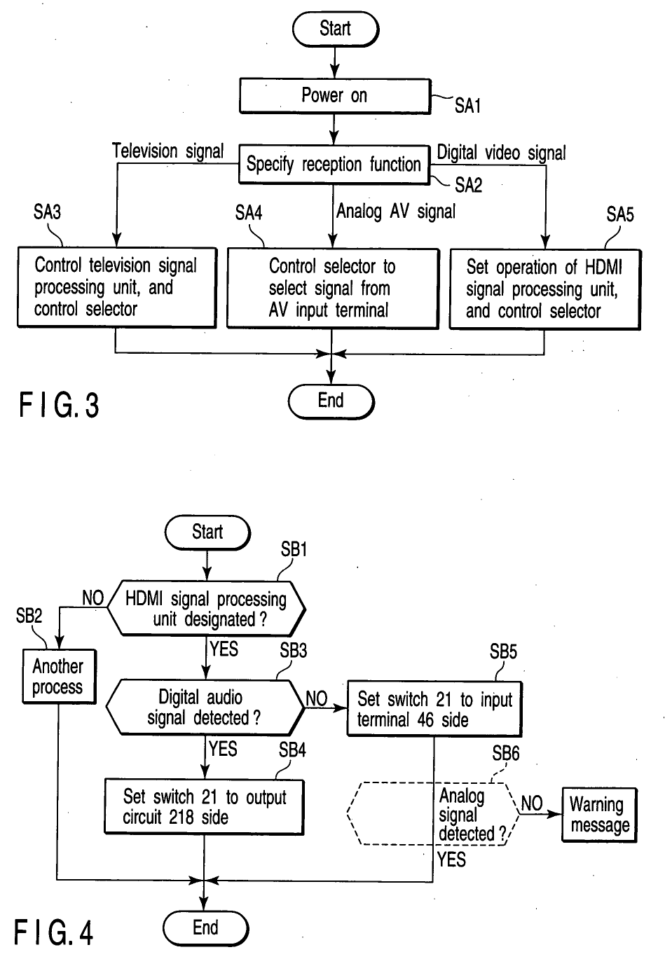

FIG. 3 is a flowchart showing the example of the operation of the video signal reception apparatus 11. When a power supply is applied in step SA1, the control unit 23 specifies the selected reception function in step SA2.

In this case, when receiving the TV broadcast signal, the control unit 23 controls the TV signal processing unit 14 in step SA3. At this time, the control unit 23 also controls the selector 15 to select the analog video signal and analog audio signal output from the TV signal processing unit 14, and the process ends.

Alternatively, when it is determined that the reception of the analog video signal and analog audio signal is selected in step SA2, the control unit 23 controls, in step SA4, the selector 15 to select the analog video signal and analog audio signal input to the AV input terminal 16, and the process ends.

When it is determined that the reception of the digital video signal complying with the HDMI standard is selected in step SA2, the control unit 23 sets the operation of the HDMI signal processing unit 20 in step SA5, and controls the selector 15 to select the analog video signal and analog audio signal output from this HDMI signal processing unit 20. Then, the process ends.

As the operation settings of the HDMI signal processing unit 20, for example, the HDMI control unit 221 analyzes the compression scheme of the video signal, aspect ratio information, scanning line count information, pixel count information, field frequency information or frame frequency information in accordance with the control information transmitted via the HDMI connector 19. The HDMI control unit 221 then sets block functions of the processing unit into processing states applying to these attributes. In the audio signal processing as well, the HDMI control unit 221 sets the audio processing system such that the block functions apply to these transmitted attributes.

FIG. 4 is a flowchart showing the example of the control operation of the HDMI signal processing unit 20 and the control unit 221 performed after the operation setting of the HDMI signal processing unit 20.

When the operation of the HDMI signal processing unit 20 is not designated, the control unit 23 receives a response signal. Accordingly, a process shifts to another operation (step SB2). When it is determined that the operation of the HDMI signal processing unit 20 is designated (step SB1), it is determined that the digital audio signal is detected or not (step SB3). If the digital audio signal is detected, the switch 21 is controlled to select the output from the output circuit 218 (step SB4). Alternatively, when the digital audio signal is not detected, the switch 21 is controlled to select the output from the input terminal 46 (step SB5).

Note that, in additional step SB6, it may be determined whether the analog audio signal is output, because a user may forget to connect the connection cable of the analog audio signal. When the analog audio signal is not detected, a warning message may be displayed, or an alarm sound may be output.

That is, the control unit 23 checks the input of the analog audio signal when the switch 21 selects the output from the analog audio signal input terminal 46. When the analog audio signal is not input, the warning message is output. At the same time, the power supply of the audio signal processing system of the HDMI signal processing unit 20 may be turned off or switched to a low power state such that excessive power is not consumed.

Although the user may be mistaken to use a HDMI-compatible device as a DVI-compatible device, and connect the HDMI device to the video signal reception apparatus 11 via the conversion cable bus 41 and the analog audio cable, audio playback can be executed with no problem, since the HDMI-compatible device can also be connected to the conversion cable bus 41 and the HDMI connector 19 via analog audio cable.

In the above embodiment, for example, in addition to the audio detection unit 22, a TV broadcast receiver using a CRT (Cathode Ray Tube), a TV broadcast receiver using a liquid crystal display, and a projection video display apparatus may serve as the video signal reception apparatus 11.

Also, as an external device 17 which supplies the digital video signal complying with the HDMI standard to this video signal reception apparatus 11, for example, a DVD (Digital Versatile Disk) player, D (digital)-VHS (Video Home System) recorder, set-top box, and digital video camera are available.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A video signal reception apparatus comprising:
an analog audio signal input unit;
an HDMI connector which receives a digital signal supplied via an HDMI cable complying with an HDMI standard;
a demultiplexing unit which demultiplexes a digital video signal and a digital audio signal from the digital signal received via the HDMI connector;
a video information processing unit which decodes the demultiplexed digital video signal, and outputs an analog video signal;
an audio information processing unit which decodes the demultiplexed digital audio signal, and outputs an analog audio signal;
a switch which selects one of the analog audio signal from the audio information processing unit, and the analog audio signal from the analog audio signal input unit;
an audio output unit which outputs the analog audio signal selected by the switch; and
a control unit which controls selection of the analog audio signal from the audio information processing unit by the switch when the digital audio signal received via the HDMI connector is present, and controls selection of the analog audio signal from the analog audio signal input unit by the switch when the digital audio signal is absent.

2. An apparatus according to claim 1, wherein the control unit detects whether the digital audio signal is present.

3. An apparatus according to claim 1, wherein the control unit detects, on the basis of attribute information pertaining to the audio signal received via the HDMI connector, whether the digital audio signal is present.

4. An apparatus according to claim 1, wherein the control unit detects whether the analog audio signal output from the analog audio signal input unit is present, and outputs information of a warning message when the analog audio signal from the analog audio signal input unit needs to be selectively controlled although the analog audio signal output from the analog audio signal input unit is absent.

5. An apparatus according to claim 1, wherein the control unit supplies a mute signal to the audio output unit until the analog audio signal to be selected by the switch is determined.

6. A video signal reception method which is applied to an apparatus including an analog audio signal input unit, an HDMI connector which receives a digital signal supplied via an HDMI cable complying with an HDMI standard, a demultiplexing unit which demultiplexes a digital video signal and a digital audio signal from the digital signal received via the HDMI connector, a video information processing unit which decodes the demultiplexed digital video signal, and outputs an analog video signal, an audio information processing unit which decodes the demultiplexed digital audio signal, and outputs an analog audio signal, a switch which selects one of the analog audio signal from the audio information processing unit, and the analog audio signal from the analog audio signal input unit, and an audio output unit which outputs the analog audio signal selected by the switch, comprising:
controlling selection of the analog audio signal from the audio information processing unit by the switch when the digital audio signal received via the HDMI connector is present; and
controlling selection of the analog audio signal from the analog audio signal input unit by the switch when the digital audio signal is absent.

7. A method according to claim 6, further comprising supplying a mute signal to the audio output unit until a state of the switch is determined.
